(19) United States
(12) Patent Application Publication
(10) Pub. No.: US 2026/0305043 A1
(43) Pub. Date: Oct. 1, 2026

(54) Display Device

(71) Applicant: LG Display Co., Ltd., Seoul (KR)

(72) Inventor: Hyeonho Son, Goyang-si (KR)

(21) Appl. No.: 19/418,473

(22) Filed: Dec. 12, 2025

(30) Foreign Application Priority Data
Mar. 26, 2025 (KR) 10-2025-0038620

(51) Int. Cl. H10H 29/856

(52) U.S. Cl. CPC H10H 29/856

(57) ABSTRACT

A display device includes a transparent display panel configured to emit light on both sides, and a mirror disposed on a rear surface of the display panel, wherein a first light displaying a front image on a front surface of the display panel is emitted to the front surface of the display panel, and a second light displaying a rear image on a rear surface of the display panel is reflected by the mirror to be emitted to the front surface of the display panel. Accordingly, a mirror is disposed on the rear surface of the display panel to reflect the second light emitted to the rear surface of the display panel back to the front surface of the display panel. Accordingly, a stereoscopic image composed of a combination of the front image and the rear image having a sense of depth may be displayed.

### CROSS-REFERENCE TO RELATED APPLICATIONS

This application claims the priority of Republic of Korea Patent Application No. 10-2025-0038620 filed on Mar. 26, 2025, in the Korean Intellectual Property Office, the disclosure of which is incorporated herein by reference.

### FIELD

The present disclosure relates to a display device such as a display device using a light emitting diode (LED), and more particularly, to a display device capable of displaying a three-dimensional image.

### BACKGROUND

Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, recently, a display device including an LED is attracting attention as a next-generation display device. Since the LED is made of an inorganic material rather than an organic material, reliability is excellent, and a lifespan thereof is longer than that of a liquid crystal display device or an organic light emitting display device. Further, the LED has a fast lighting speed, excellent luminous efficiency, and a strong impact resistance so that stability is excellent and an image having a high luminance can be displayed.

### SUMMARY

An object to be achieved by the present disclosure is to provide a display device capable of displaying a three-dimensional image.

Another object to be achieved by the present disclosure is to provide a display device capable of implementing a stereoscopic image at a reduced or minimum cost.

Still another object to be achieved by the present disclosure is to provide a lightweight display device including only a minimum number of components to implement a stereoscopic image.

Still another object to be achieved by the present disclosure is to provide a display device in which a stereoscopic image viewing area is not limited.

Objects of the present disclosure are not limited to the above-mentioned objects, and other objects, which are not mentioned above, can be clearly understood by those skilled in the art from the following descriptions.

A display device according to an exemplary embodiment of the present disclosure includes a transparent display panel configured to emit light on both sides, and a mirror disposed on a rear surface of the display panel, wherein a first light displaying a front image on a front surface of the display panel is emitted to the front surface of the display panel, and a second light displaying a rear image on a rear surface of the display panel is reflected by the mirror to be emitted to the front surface of the display panel. Accordingly, a mirror is disposed on the rear surface of the display panel to reflect the second light emitted to the rear surface of the display panel back to the front surface of the display panel. Accordingly, a stereoscopic image composed of a combination of the front image and the rear image having a sense of depth may be displayed.

A display device according to another exemplary embodiment of the present disclosure includes: a display panel including a transmissive area and a first pixel and a second pixel disposed outside the transmissive area, the first pixel being configured to emit front light toward a front surface of the display panel, and the second pixel being configured to emit rear light toward a rear surface of the display panel; and a mirror spaced apart from the display panel and configured to reflect the rear light such that the reflected rear light travels to the front surface of the display panel through the transmissive area.

Other detailed matters of the embodiments are included in the detailed description and the drawings.

According to the present disclosure, a 3D image may be easily implemented using a transparent double-sided light emitting display panel and a mirror.

According to the present disclosure, it is possible to form a display device capable of realizing a stereoscopic image only with a transparent double-sided light emitting display panel and a mirror, thereby reducing manufacturing cost of the display device.

According to the present disclosure, it is possible to form a display device capable of realizing a stereoscopic image only with a transparent double-sided light emitting display panel and a mirror, thereby reducing the weight of the display device.

According to the present disclosure, since there is no limitation on a viewing area for viewing a stereoscopic image, it is possible to view a stereoscopic image from various angles and positions.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a display device according to an exemplary embodiment of the present disclosure.

FIG. 2 is a schematic plan view of a display panel of a display device according to an exemplary embodiment of the present disclosure.

FIG. 3 is a schematic cross-sectional view of a display panel of a display device according to an exemplary embodiment of the present disclosure.

FIGS. 4 to 6 are schematic plan views for explaining the arrangement of a plurality of pixels of a display panel of a display device according to an exemplary embodiment of the present disclosure.

FIG. 7 is a schematic enlarged plan view of a first pixel of a display panel of a display device according to an exemplary embodiment of the present disclosure.

FIG. 8 is a cross-sectional view of a first pixel of a display panel of a display device according to an exemplary embodiment of the present disclosure.

FIG. 9 is a schematic enlarged plan view of a second pixel of a display panel of a display device according to an exemplary embodiment of the present disclosure.

FIG. 10 is a cross-sectional view of a second pixel of a display panel of a display device according to an exemplary embodiment of the present disclosure.

FIG. 11 is a view for explaining an example in which a display device according to an exemplary embodiment of the present disclosure is used.

FIG. 12 is a view for explaining that a display device according to an exemplary embodiment of the present disclosure displays a stereoscopic image.

FIG. 13 is a schematic cross-sectional view of a display device according to an exemplary embodiment of the present disclosure.

FIG. 14 is a schematic cross-sectional view of a display device according to another embodiment of the present disclosure.

FIG. 15 is a schematic cross-sectional view for explaining a position of a virtual display panel of a display device according to another exemplary embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” “composed of,” “formed of,” “made of,” or the like used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be disposed on the other element or layer directly or another layer or another element may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure, and vice versa.

Spatially relative terms, such as “below,” “lower,” “on,” “above”, “upper” and the like, can be used to describe a correlation between various elements (e.g., layers, films, areas, components, or the like) as shown in the drawings. The spatially relative terms are to be understood as terms including different orientations of the elements in use or in operation in addition to the orientation depicted in the drawings. For example, if the elements shown in the drawings are turned over, elements described as “below” other elements would be oriented “above” or “on” other elements and elements described as “above” or “on” other elements would be oriented “below” other elements.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to the drawings.

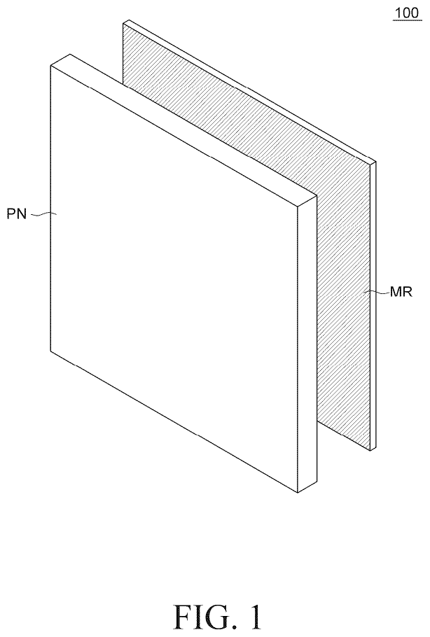

FIG. 1 is a schematic perspective view of a display device according to an exemplary embodiment of the present disclosure. In FIG. 1, for the convenience of description, among various components of the display device 100, only a display panel PN and a mirror MR are illustrated.

Referring to FIG. 1, a display device 100 includes a display panel PN and a mirror MR disposed on a rear surface of the display panel PN.

The display panel PN is configured to display images, and images may be displayed on a front surface and the rear surface of the display panel PN. The display panel PN may be a double-sided light emitting display panel PN in which images are displayed on both surfaces of the display panel PN. Further, the display panel PN may be a transparent display panel PN. A background on the rear surface of the display panel PN may be seen from the front surface of the display panel PN, and a background on the front surface of the display panel PN may be seen from the rear surface of the display panel PN. Accordingly, the display panel PN of the display device 100 according to the exemplary embodiment of the present disclosure may be a transparent double-sided light emitting display panel PN in which images are displayed on both surfaces and configured to be transparent.

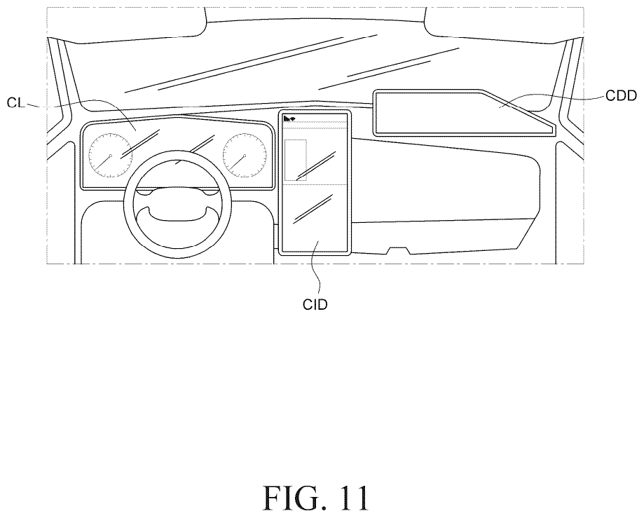

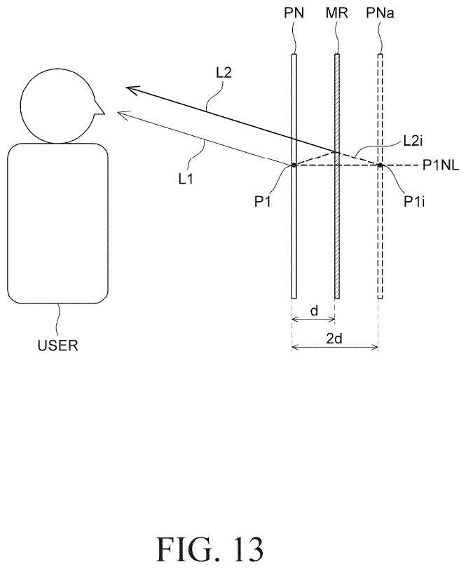

The mirror MR is a configuration for giving a three-dimensional effect to an image displayed on the front surface of the display panel PN. The mirror MR may be disposed to be spaced apart from the display panel PN at a predetermined interval. The mirror MR is disposed on the rear surface of the display panel PN to reflect light emitted from the rear surface of the display panel PN toward the front surface of the display panel PN. The user USER (see for example FIG. 13) looking at the front surface of the display panel PN may view an existing image displayed on the front surface of the display panel PN and an image on the rear surface of the display panel PN reflected by the mirror MR. In this case, while the image on the rear surface is reflected by the mirror MR and displayed on the front surface of the display panel PN, the image is visually recognized as if displayed on a plane different from the image on the front surface of the display panel PN and may have a three-dimensional effect. A method of implementing a stereoscopic image using a mirror MR will be described later with reference to FIGS. 11 to 15.

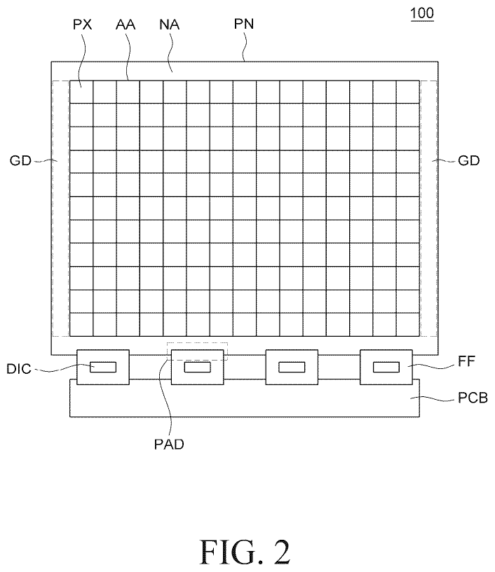

Hereinafter, a display panel PN of a display device 100 according to an exemplary embodiment of the present disclosure will be described in detail with reference to FIGS. 2 to 10.

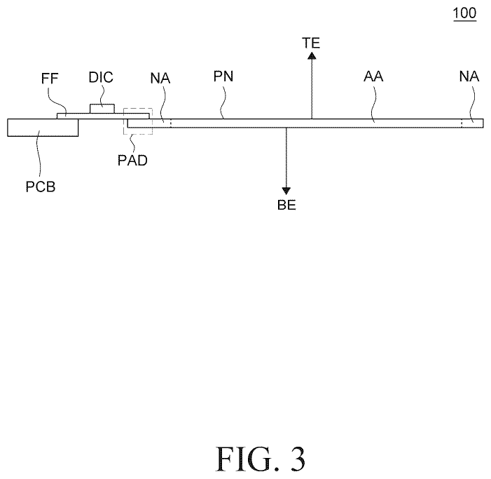

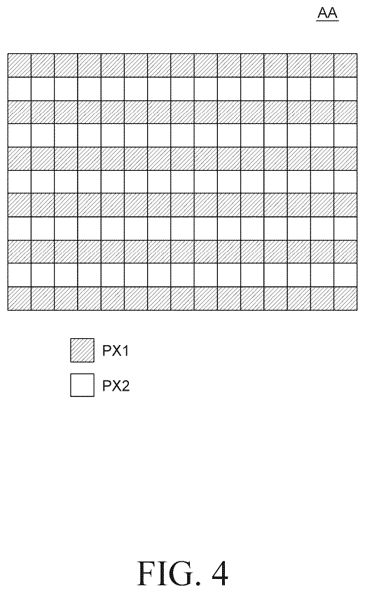

FIG. 2 is a schematic plan view of a display panel of a display device according to an exemplary embodiment of the present disclosure. FIG. 3 is a schematic cross-sectional view of a display panel of a display device according to an exemplary embodiment of the present disclosure. FIGS. 4 to 6 are schematic plan views for explaining the arrangement of a plurality of pixels of a display panel of a display device according to an exemplary embodiment of the present disclosure.

Referring to FIGS. 2 and 3, the display panel PN includes a display area AA and a non-display area NA. The display area AA is an area where an image is displayed. In the display area AA, a plurality of pixels PX and a pixel circuit for driving the plurality of pixels PX may be disposed. The non-display area NA is an area where no image is displayed and may extend from at least one portion of the display area AA. Various circuits and lines for driving the pixel PX may be disposed in the non-display area NA.

The display panel PN may emit light on both sides as described above, and may emit front light (an example of a first light) toward the display area AA of the front surface of the display panel PN and may emit rear light (an example of a second light) toward the display area AA of the rear surface of the display panel PN.

A gate driver GD is disposed in the non-display area NA. For example, the gate driver GD may be disposed in the non-display area NA on the left and right sides of the display area AA. The gate driver GD may provide a signal to a plurality of lines in the display area AA. For example, the gate driver GD may include a scan driver configured to provide a scan signal to a scan line SL and an emission control driver configured to provide an emission control signal to an emission control line.

A plurality of flexible films FF is connected to a pad part or pad area PAD of the display panel PN. The plurality of flexible films FF may be films in which various components are disposed on a base film having flexibility. For example, a driving IC DIC such as a gate driver IC or a data driver IC may be disposed on the plurality of flexible films FF. The driving IC DIC may be a component that processes data and a driving signal for displaying an image. The driving IC DIC may be disposed by a chip on glass (COG), a chip on film (COF), or a tape carrier package (TCP) method depending on a mounting method, but the exemplary embodiments of the present disclosure are not limited thereto.

A printed circuit board PCB is connected to the plurality of flexible films FF. The printed circuit board PCB is electrically connected to the flexible film FF and may be a component that supplies a signal to the driving IC DIC. Various components for supplying various signals to the driving IC DIC may be disposed on the printed circuit board PCB. For example, various components, such as a timing controller, a power management integrated circuit (PMIC), a memory, or a processor, may be disposed on the printed circuit board PCB, but the exemplary embodiments of the present disclosure are not limited thereto.

Referring to FIGS. 3 to 6 together, the plurality of pixels PX includes a plurality of first pixels PX1 and a plurality of second pixels PX2. The plurality of first pixels PX1 may be pixels PX that emit front light TE toward the front surface of the display panel PN, and the plurality of second pixels PX2 may be pixels PX that emit rear light BE toward the rear surface of the display panel PN. Accordingly, the plurality of first pixels PX1 may be defined as the front light emitting pixels PX, and the plurality of second pixels PX2 may be defined as the rear light emitting pixels PX.

The plurality of first pixels PX1 and the plurality of second pixels PX2 may be variously arranged in the display area AA. For example, referring to FIG. 4, the plurality of first pixels PX1 and the plurality of second pixels PX2 may be disposed in different rows. The plurality of first pixels PX1 and the plurality of second pixels PX2 may be alternately disposed in the same column.

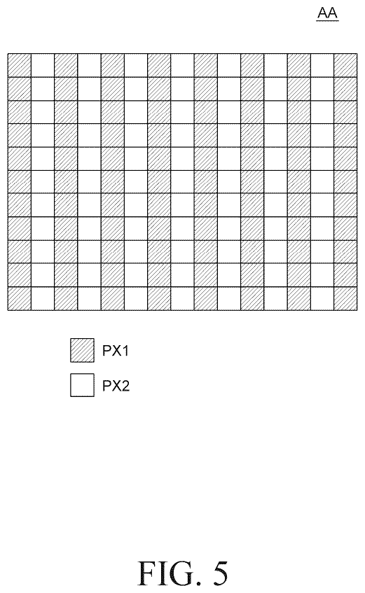

For example, referring to FIG. 5, the plurality of first pixels PX1 and the plurality of second pixels PX2 may be disposed in different columns. The plurality of first pixels PX1 and the plurality of second pixels PX2 may be alternately disposed in the same row.

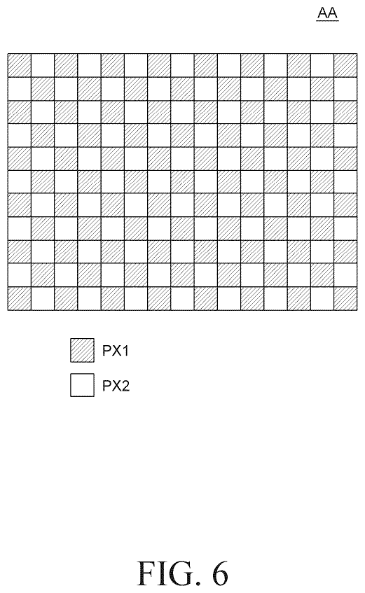

For example, referring to FIG. 6, the plurality of first pixels PX1 and the plurality of second pixels PX2 may be alternately disposed in the same row and in the same column. The plurality of first pixels PX1 and the plurality of second pixels PX2 may be alternately disposed in the row direction and the column direction and may be disposed in a mosaic pattern.

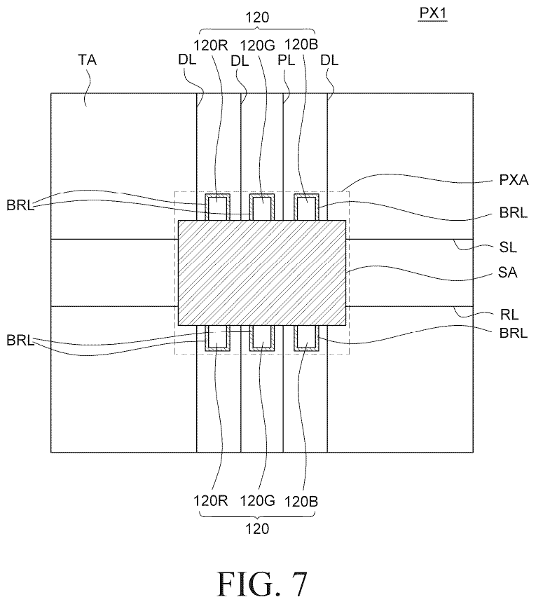

Hereinafter, a plurality of first pixels PX1 and a plurality of second pixels PX2 of the display device 100 according to the embodiment of the present disclosure will be described in more detail with reference to FIGS. 7 to 10.

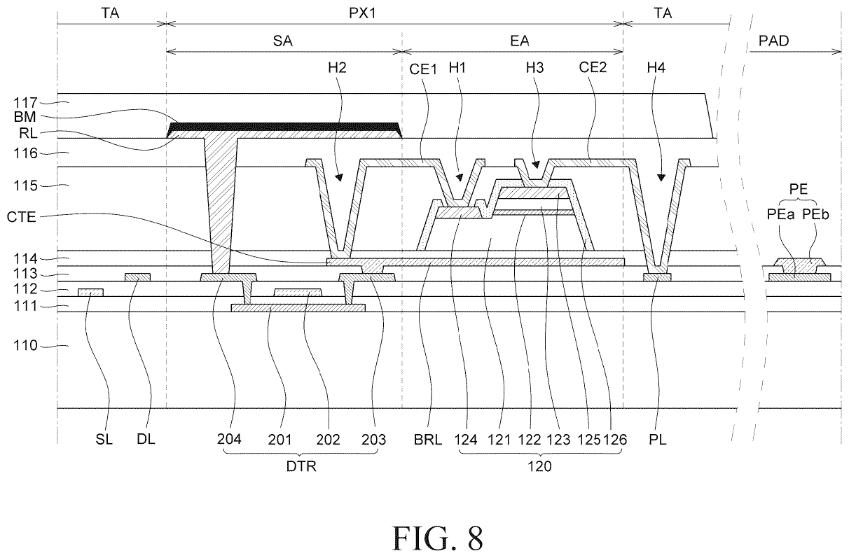

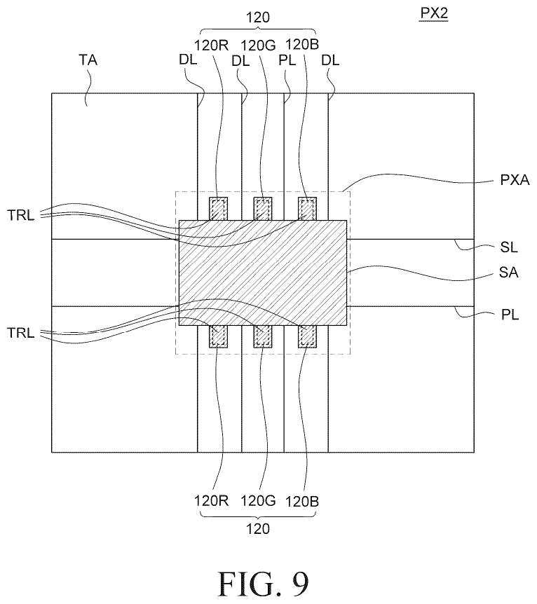

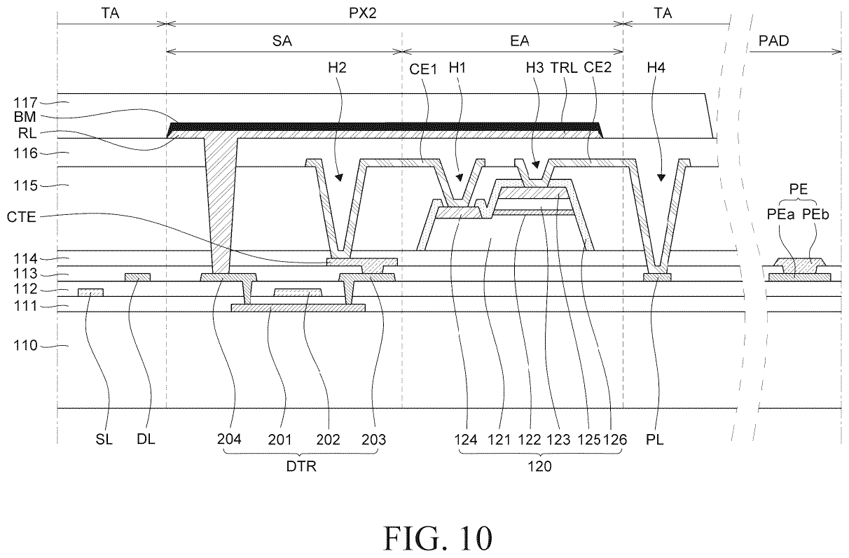

FIG. 7 is a schematic enlarged plan view of a first pixel of a display panel of a display device according to an exemplary embodiment of the present disclosure. FIG. 8 is a cross-sectional view of a first pixel of a display panel of a display device according to an exemplary embodiment of the present disclosure. FIG. 9 is a schematic enlarged plan view of a second pixel of a display panel of a display device according to an exemplary embodiment of the present disclosure. FIG. 10 is a cross-sectional view of a second pixel of a display panel of a display device according to an exemplary embodiment of the present disclosure.

Referring to FIGS. 7 and 9, the display area AA includes a plurality of pixel areas PXA composed of an emission area EA and a non-transmissive area SA, and a transmissive area TA between the plurality of pixel areas PXA.

The transmissive area TA is a transparent area, and a background opposite to the display panel PN may be seen through the transmissive area TA. The transmissive area TA may be disposed to surround each of the plurality of emission areas EA. The transmissive area TA may be formed in a mesh shape.

The plurality of pixel areas PXA is areas in which a plurality of pixels PX is disposed to display images. One or more pixels PX may be disposed in each of the plurality of pixel areas PXA. The plurality of pixel areas PXA may be disposed to be spaced apart from each other with the transmissive area TA interposed therebetween. The plurality of pixel areas PXA may be disposed in a plurality of rows and a plurality of columns.

Each of the plurality of pixel areas PXA includes an emission area EA and a non-transmissive area SA. The emitting area EA is an area in which light from the light emitting element 120 is emitted. In the emission area EA, light from the light emitting element 120 may be emitted to any one of the front surface or the rear surface of the display panel PN depending on the type of pixel PX.

The non-transmissive area SA is an opaque area, and is an area through which light does not pass through the display panel PN. The non-transmissive area SA may be disposed adjacent to the emission area EA. A circuit of the pixel PX may be disposed in the non-transmissive area SA. For example, various driving elements such as a plurality of transistors and capacitors may be disposed in the non-transmissive area SA.

A pixel PX is disposed in each of the plurality of pixel areas PXA. Each of the plurality of pixels PX includes a plurality of light emitting elements 120 and a plurality of pixel circuits to independently emit light. In this case, at least one light emitting element 120 and the pixel circuit may constitute one sub-pixel, and one pixel PX may be defined as composed of a plurality of sub-pixels.

A plurality of lines are disposed in the display area AA. The plurality of lines are connected to the plurality of pixels PX and configured to transmit signals. For example, the plurality of lines may include a scan line SL and a reference line RL extending in a row direction, and a plurality of data lines DL and a power line PL extending in a column direction. However, the configuration of the plurality of lines may vary according to the circuit configuration of the pixel PX, but is not limited thereto.

Referring to FIGS. 7 and 8, the substrate 110 is a component for supporting various components included in the display panel PN and may be formed of an insulating material. For example, the substrate 110 may be made of glass, resin, or the like. In addition, the substrate 110 may include polymer or plastic, or may be made of a material having flexibility.

The driving transistor DTR is disposed in each of the plurality of pixels PX on the substrate 110. The driving transistor DTR may be disposed in the non-transmissive area SA. The driving transistor DTR includes an active layer 201, a gate electrode 202, a source electrode 203, and a drain electrode 204. The active layer 201 is disposed on the substrate 110. The active layer 201 may be formed of a semiconductor material such as an oxide semiconductor, amorphous silicon, or polysilicon, but is not limited thereto. A buffer layer may be disposed between the substrate 110 and the active layer 201, and the buffer layer may reduce the penetration of moisture and/or impurities through the substrate 110.

The first insulating layer 111 is disposed on the active layer 201. The first insulating layer 111 is also referred to as a gate insulating layer, and may be configured as a single layer made of silicon oxide (SiOx) or silicon nitride (SiNx) or a multilayer made of silicon oxide (SiOx) and/or silicon nitride (SiNx) as an insulating layer for insulating the active layer 201 and the gate electrode 202. However, the present disclosure is not limited thereto.

The gate electrode 202 is disposed on the first insulating layer 111. The gate electrode 202 may be made of a conductive material, for example, copper (Cu), aluminum (Al), molybdenum (Mo), nickel (Ni), titanium (Ti), chromium (Cr), or an alloy thereof, but is not limited thereto.

Meanwhile, the scan line SL is disposed on the first insulating layer 111 together with the gate electrode 202. The scan line SL may be formed of the same material and process as the gate electrode 202.

The second insulating layer 112 is disposed on the gate electrode 202. Contact holes through which the source electrode 203 and the drain electrode 204 are connected to the active layer 201 are formed in the second insulating layer 112 and the first insulating layer 111. The second insulating layer 112 is a passivation layer which protects components below the second insulating layer 112 and may be configured by a single layer made of silicon oxide (SiOx) or silicon nitride (SiNx) or a double layer made of silicon oxide (SiOx) and/or silicon nitride (SiNx), but is not limited thereto.

The source electrode 203 and the drain electrode 204 which are electrically connected to the active layer 201 are disposed on the second insulating layer 112. The source electrode 203 and the drain electrode 204 may be configured by a conductive material, such as copper (Cu), aluminum (Al), molybdenum (Mo), nickel (Ni), titanium (Ti), chromium (Cr), or an alloy thereof, but are not limited thereto.

Meanwhile, the data line DL and the power line PL are disposed on the second insulating layer 112 together with the source electrode 203 and the drain electrode 204. The data line DL and the power line PL may be formed of the same material and process as the source electrode 203 and the drain electrode 204.

The third insulating layer 113 is disposed on the data line DL, the driving transistor DTR, and the power line PL. The third insulating layer 113 is a layer which protects components below the third insulating layer 113 and may be configured by a single layer made of silicon oxide (SiOx) or silicon nitride (SiNx) or a double layer of silicon oxide (SiOx) and/or silicon nitride (SiNx), but is not limited thereto. Further, the third insulating layer 113 may be a planarization layer formed of an organic material to alleviate a step under the third insulating layer 113.

The contact electrode CTE electrically connected to the source electrode 203 is disposed on the third insulating layer 113. The contact electrode CTE is connected to the source electrode 203 through a contact hole of the third insulating layer 113.

Referring to FIG. 8, in the first pixel PX1, the contact electrode CTE extends to the emission area EA to be disposed below the light emitting element 120, and a part of the contact electrode CTE disposed below the light emitting element 120 may be defined as a lower reflective layer BRL. The lower reflective layer BRL emits light from the light emitting element 120 in a direction away from the substrate 110 which is a front surface of the transparent double-sided light emitting display panel PN. In the plan view, an area of the lower reflective layer BRL may be larger than an area of the light emitting element 120. The lower reflective layer BRL may overlap the entire light emitting element 120. In order to fully reflect the light of the light emitting element 120, the lower reflective layer BRL is formed to have a larger area than the lower area of the light emitting element 120. The contact electrode CTE and the lower reflective layer BRL may be formed of a metal material having a high reflectance, for example, silver (Ag), aluminum (Al), or an alloy thereof, but are not limited thereto. In the case of silver (Ag), since pure silver (Ag) may react with oxygen or nitrogen to degrade the reflectivity, the contact electrode CTE and the lower reflective layer BRL may be formed as a multilayer of ITO/Ag/ITO, or may be formed by adding impurities of palladium (Pd) or copper (Cu).

Further, the source electrode 203, the lower reflective layer BRL, the first electrode 124 of the light emitting element 120, and the first semiconductor layer 121 of the light emitting element 120 may be electrically connected to each other to be in an equipotential state. Accordingly, a migration phenomenon of the lower reflective layer BRL due to a potential difference between the lower portion of the light emitting element 120 and the lower reflective layer BRL may be prevented.

The adhesive layer 114 is disposed on the contact electrode CTE. The adhesive layer 114 is a layer for fixing the light emitting element 120 on the substrate 110 and may electrically insulate the lower reflective layer BRL including a metal material and the light emitting element 120. However, in case that the light emitting element 120 is a vertical type light emitting element 120 in which the first electrode 124 is disposed below the first semiconductor layer 121 and the second electrode 125 is disposed above the second semiconductor layer 123, the adhesive layer 114 may include a conductive material so that the first electrode 124 of the light emitting element 120 and the lower reflective layer BRL may be electrically connected with each other, but is not limited thereto.

The adhesive layer 114 may be made of a thermosetting material or a photocurable material. The adhesive layer 114 may be any one of adhesive polymer, epoxy resist, UV resin, polyimide series, acrylate series, urethane series, and polydimethylsiloxane (PDMS), but is not limited thereto.

The plurality of light emitting elements 120 is disposed in each of the plurality of pixels PX on the adhesive layer 114. The light emitting element 120 is an element which emits light by a current. The plurality of light emitting elements 120 may include a red light emitting element 120R which emits red light, a green light emitting element 120G which emits green light, and a blue light emitting element 120B which emits blue light and implements light of various colors including white by a combination thereof. For example, the light emitting element 120 may be a light emitting element (LED) or a micro LED, but is not limited thereto. For example, two red light emitting elements 120R, two green light emitting elements 120G, and two blue light emitting elements 120B may be disposed in one pixel PX.

The light emitting element 120 is disposed to completely overlap the adhesive layer 114. Even though in the drawing, it is described that the light emitting element 120 is a lateral type in which the first electrode 124 and the second electrode 125 are disposed side by side, it is not necessarily limited thereto. For example, the light emitting element 120 may be a vertical type in which the first electrode 124 and the second electrode 125 overlap each other or a flip-chip type in which the first electrode 124 and the second electrode 125 are in contact with the substrate.

Each of the plurality of light emitting elements 120 includes a first semiconductor layer 121, a light emitting layer 122, a second semiconductor layer 123, a first electrode 124, a second electrode 125, and an encapsulation film 126.

The first semiconductor layer 121 is disposed on the adhesive layer 114, and the second semiconductor layer 123 is disposed on the first semiconductor layer 121. The first semiconductor layer 121 and the second semiconductor layer 123 may be layers formed by doping n-type and p-type impurities into a specific material. For example, one of the first semiconductor layer 121 and the second semiconductor layer 123 may be a layer formed by doping n-type impurities into a specific material, and the other one of the first semiconductor layer 121 and the second semiconductor layer 123 may be a layer formed by doping p-type impurities into a specific material. For example, the first semiconductor layer 121 and the second semiconductor layer 123 may be layers formed by doping n-type and p-type impurities into a material such as gallium nitride (GaN), indium aluminum phosphide (InAlP), or gallium arsenide (GaAs). For example, one of the first semiconductor layer 121 and the second semiconductor layer 123 may be a layer formed by doping n-type impurities into a material such as gallium nitride (GaN), indium aluminum phosphide (InAlP), or gallium arsenide (GaAs), and the other one of the first semiconductor layer 121 and the second semiconductor layer 123 may be a layer formed by doping p-type impurities into a material such as gallium nitride (GaN), indium aluminum phosphide (InAlP), or gallium arsenide (GaAs). Further, the p-type impurity may be magnesium (Mg), zinc (Zn), beryllium (Be), and the like, and the n-type impurity may be silicon (Si), germanium (Ge), tin (Sn), and the like, but not limited thereto.

The light emitting layer 122 is disposed between the first semiconductor layer 121 and the second semiconductor layer 123. The light emitting layer 122 may receive holes and electrons from the first semiconductor layer 121 and the second semiconductor layer 123 to emit light. The light emitting layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 is an electrode which electrically connects the driving transistor DTR and the first semiconductor layer 121. In this case, the first semiconductor layer 121 may be a semiconductor layer doped with an n-type impurity, and the first electrode 124 may be a cathode. The first electrode 124 may be disposed on an upper surface of the first semiconductor layer 121 exposed from the light emitting layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 may be disposed on the upper surface of the second semiconductor layer 123. The second electrode 125 is an electrode for electrically connecting the power line PL and the second semiconductor layer 123. In this case, the second semiconductor layer 123 may be a semiconductor layer doped with a p-type impurity, and the second electrode 125 may be an anode. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation film 126 which encloses the first semiconductor layer 121, the emission layer 122, the second semiconductor layer 123, the first electrode 124, and the second electrode 125 is disposed. The encapsulation film 126 may be formed of an insulating material to protect the first semiconductor layer 121, the emission layer 122, and the second semiconductor layer 123. The encapsulation film 126 may not cover a part of the first electrode 124 and a part of the second electrode 125, but may cover only edges of the first electrode 124 and the second electrode 125. The first electrode 124 and the second electrode 125 which are not covered by the encapsulation film 126 are in contact with the first connection electrode CE1 and the second connection electrode CE2, respectively.

The fourth insulating layer 115 is disposed on the light emitting element 120. The fourth insulating layer 115 may be formed of a single layer or a double layer. The fourth insulating layer 115 may be formed of an organic material such as photo acryl, polyimide, benzocyclobutene resin, or acrylate resin, but is not limited thereto.

The fourth insulating layer 115 is disposed to cover the front surface of the substrate 110 and is disposed adjacent to the side surface of the light emitting element 120 to fix the light emitting element 120 onto the substrate 110. In addition, during the process of transferring the light emitting element 120 to the substrate 110, the encapsulation film 126 may be partially scratched or peeled off, so that the light emitting element 120 may be disposed on the substrate 110 with a portion of the first semiconductor layer 121 exposed. The fourth insulating layer 115 is formed to surround the side surface of the light emitting element 120 to electrically insulate the first semiconductor layer 121 and the second semiconductor layer 123 of the light emitting element 120.

The fourth insulating layer 115 may be thicker than the light emitting element 120. Accordingly, the fourth insulating layer 115 may overlap an upper portion of the light emitting element 120. The fourth insulating layer 115 may cover the encapsulation film 126 between the first electrode 124 and the second electrode 125.

The fourth insulating layer 115 includes a first contact hole H1 for connecting the light emitting element 120 and the first connection electrode CE1, a second contact hole H2 for connecting the first connection electrode CE1 and the contact electrode CTE, a third contact hole H3 for connecting the light emitting element 120 and the second connection electrode CE2, and a fourth contact hole H4 for connecting the second connection electrode CE2 and the power line PL. In other words, the first connection electrode CE1 electrically connects the light emitting element 120 and the driving transistor DTR through the first contact hole H1 and the second contact hole H2, and the second connection electrode CE2 electrically connects the light emitting element 120 and the power line PL through the third contact hole H3 and the fourth contact hole H4. The second contact hole H2 is formed not only in the fourth insulating layer 115 but also in the adhesive layer 114, and the fourth contact hole H4 is formed not only in the fourth insulating layer 115 but also in the adhesive layer 114 and the third insulating layer 113. The first contact hole H1 and the third contact hole H3 may be disposed in the emission area EA, the second contact hole H2 may be disposed in the non-transmissive area SA, and the fourth contact hole H4 may be disposed in the transmissive area TA. However, the fourth contact hole H4 is not limited thereto and may be disposed in the non-transmissive area SA.

The first connection electrode CE1 and the second connection electrode CE2 are physically separated from each other on the encapsulation film 126 and the fourth insulating layer 115 between the first electrode 124 and the second electrode 125. Accordingly, the first semiconductor layer 121 and the second semiconductor layer 123 are electrically insulated so that the light emitting element 120 may emit light normally.

The first pixel PX1 is a front light emitting pixel PX in which light of the light emitting element 120 is directed toward the top of the light emitting element 120 and the substrate 110. Therefore, the first connection electrode CE1 and the second connection electrode CE2 disposed in the first pixel PX1 are made of a transparent conductive material. The transparent conductive material may be indium tin oxide (ITO) or indium zinc oxide (IZO), but is not limited thereto.

A fifth insulating layer 116 is disposed on the fourth insulating layer 115. The fifth insulating layer 116 is formed in the first contact hole H1, the second contact hole H2, the third contact hole H3, and the fourth contact hole H4 to planarize the upper portion of the light emitting element 120. The fifth insulating layer 116 may be formed of an organic material such as photo acryl, polyimide, benzocyclobutene resin, or acrylate, but is not limited thereto.

The reference line RL is disposed on the fifth insulating layer 116. In FIG. 8, the reference line RL is schematically illustrated as being connected to the drain electrode 204 of the driving transistor DTR, but is not limited thereto. The reference line RL may not be directly connected to the drain electrode 204 of the driving transistor DTR, but may be connected to another component of the pixel circuit, for example, a switching element.

The reference line RL is disposed in the non-transmissive area SA and may be connected to a pixel circuit including the driving transistor DTR through contact holes formed in the fifth insulating layer 116, the fourth insulating layer 115, the adhesive layer 114, and the third insulating layer 113. The reference line RL is a reflective electrode, such as the contact electrode, and may be made of a metal material having high reflectivity, for example, silver (Ag), aluminum (Al), or an alloy thereof, but is not limited thereto. In the case of silver (Ag), since pure silver (Ag) may react with oxygen or nitrogen to degrade the reflectivity, the reference line RL may be formed as a multilayer of ITO/Ag/ITO, or may be formed by adding impurities of palladium (Pd) or copper (Cu). In the first pixel PX1, the reference line RL is not disposed in the emission area EA so that light may be emitted upward.

A black matrix BM is disposed in the non-transmissive area SA. The black matrix BM may be disposed on the reference line RL and may be an insulating material. Further, the black matrix BM may include a black material or a light absorbing material. For example, the black matrix BM may be formed of a carbon-based mixture, and specifically, may include carbon black. The black matrix BM may absorb heat that may be concentrated on the reference line RL and dissipate it to the outside, thereby extending the life of the display device 100. Further, the black matrix BM may be disposed to surround the emission area EA to suppress color mixture between the light emitting elements 120, thereby improving the quality of the display device 100.

A protective layer 117 is disposed on the fifth insulating layer 116 and the black matrix BM. The protective layer 117 is a layer for protecting components below the protective layer 117 and may be configured by a single layer or a double layer of translucent epoxy, silicon oxide (SiOx) or silicon nitride (SiNx), but is not limited thereto. The fourth insulating layer 115, the fifth insulating layer 116, and the protective layer 117 are formed in a stepwise manner so that side surfaces of the fourth insulating layer 115, the fifth insulating layer 116, and the protective layer 117 may be inclined from the substrate 110, thereby alleviating the step difference. In some cases, the protective layer 117 may be formed of a plurality of layers to cover upper and side surfaces of the fourth insulating layer 115 and the fifth insulating layer 116 to enhance prevention of moisture and oxygen penetration.

Referring to FIGS. 2, 3, 8, and 10 together, a pad area PAD is disposed in the non-display area NA on one side surface of the display panel PN. A plurality of pad electrodes PE is disposed in the pad area PAD. As described above, the flexible film FF having the driving IC DIC formed thereon may be attached to the pad electrode PE. In the pad area PAD, the pad electrode PE is exposed without disposing the adhesive layer 114, the fourth insulating layer 115, the fifth insulating layer 116, and the protective layer 117 to receive a signal from the outside through the pad electrode PE.

The pad electrode PE may include a first pad electrode PEa and a second pad electrode PEb. The first pad electrode PEa may be formed of the same material on the same layer as the source electrode 203 and the drain electrode 204 of the driving transistor DTR. The second pad electrode PEb may be formed of the same material on the same layer as the contact electrode CTE. In the drawing, only two pad electrodes PE are briefly illustrated, but the pad electrodes PE may be implemented as a triple layer or more in some cases.

FIG. 10 illustrates cross-sections of the transmissive area TA, the emission area EA, the non-transmissive area SA, and the pad area of the second pixel PX2. The light emitting element 120 is disposed in the emission area EA, a pixel circuit is disposed in the non-transmissive area SA, and a pad electrode PE is disposed in the pad area. In the drawing, a driving transistor DTR which is directly connected to the light emitting element 120 among the pixel circuits is illustrated, but is not limited thereto, and the illustrated transistor may be a switching transistor or a light emitting transistor depending on the type of pixel circuit.

In FIG. 10, there is a difference in the presence or absence and location of the lower reflective layer BRL and the upper reflective layer TRL compared to FIG. 8, and since the remaining components are applied equally, a description of redundant components will be omitted.

In the second pixel PX2 which is the rear light emitting pixel PX, the contact electrode CTE does not extend to the emission area EA, but only electrically connects the source electrode 203 of the driving transistor DTR and the first connection electrode CE1. In addition, since the second pixel PX2 is a rear light emitting pixel PX, the electrodes disposed above the light emitting element 120 need not be made of a transparent conductive material. For example, the first connection electrode CE1 and the second connection electrode CE2 are made of a transparent conductive material as in the case of the first pixel PX1 according to the convenience of the process, but are not limited thereto.

When the first connection electrode CE1 and the second connection electrode CE2 are made of transparent conductive materials, a reflective electrode is disposed on the light emitting element 120 to emit light generated from the light emitting element 120 toward the substrate 110. Specifically, the reflective electrode is disposed on the fifth insulating layer 116 in the emission area EA and is referred to as an upper reflective layer TRL.

The upper reflective layer TRL is a portion in which the reference line RL disposed in the non-transmissive area SA extends to the light emitting area EA, and overlaps the light emitting element 120. As described above, the reference line RL may be connected to the drain electrode 204 of the driving transistor DTR or may be connected to another configuration of the pixel circuit without being directly connected to the drain electrode 204 of the driving transistor DTR. The upper reflective layer TRL is not floated, but a constant voltage is applied to prevent the potential of the upper reflective layer TRL from being changed by the environment around the upper reflective layer TRL. Further, for example, when a low-potential voltage is applied to the reference line RL, the upper reflective layer TRL may mitigate a voltage drop of the low-potential voltage. In this case, if necessary, the thickness of the upper reflective layer TRL may be increased.

The upper reflective layer TRL reflects light from the light emitting element 120 toward a lower portion of the transparent double-sided light emitting display panel PN, that is, from the light emitting element 120 toward the substrate 110. In the plan view, an area of the upper reflective layer TRL is larger than an area of the light emitting element 120. Even when viewed from the cross section, the length of the upper reflective layer TRL is longer than the length of the light emitting element 120. In order to fully reflect the light of the light emitting element 120, the upper reflective layer TRL is formed to be wider than the upper area of the light emitting element 120. The reference line RL and the upper reflective layer TRL may be formed of a metal material having a high reflectance, for example, silver (Ag), aluminum (Al), or an alloy thereof, but are not limited thereto. In the case of silver (Ag), since pure silver (Ag) reacts with oxygen or nitrogen to degrade the reflectivity, the reference line RL and the upper reflective layer TRL may be formed as a multilayer of ITO/Ag/ITO, or may be formed by adding impurities of palladium (Pd) or copper (Cu). The relationship between the upper reflective layer TRL and the light emitting element 120 will be described in more detail in the following drawings.

A black matrix BM is disposed in the non-transmissive area SA. The black matrix BM may be disposed on the reference line RL and may be an insulating material. Since the second pixel PX2 is a rear light emitting pixel PX, the black matrix BM may be disposed on the light emitting element 120 in the second pixel PX2.

Hereinafter, a method of displaying a 3D image using a mirror MR and a display panel PN will be described with reference to FIGS. 11 to 13.

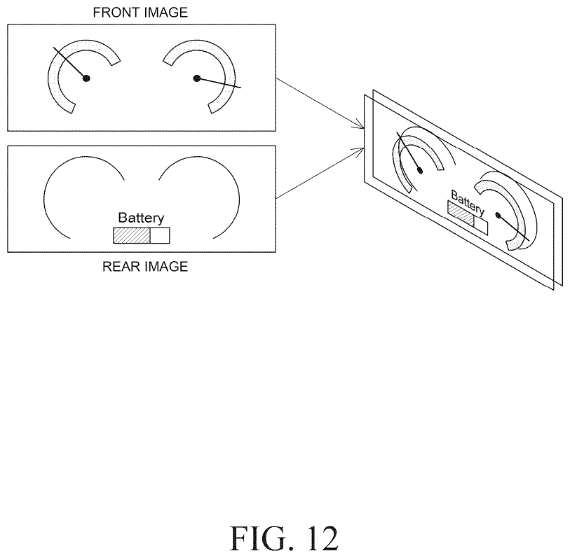

FIG. 11 is a view for explaining an example in which a display device according to an exemplary embodiment of the present disclosure is used. FIG. 12 is a view for explaining that a display device according to an exemplary embodiment of the present disclosure displays a stereoscopic image. FIG. 13 is a schematic cross-sectional view of a display device according to an exemplary embodiment of the present disclosure. Specifically, FIG. 11 is a view illustrating a case in which a display device is used for a vehicle, FIG. 12 is a schematic exemplary view for a front image and a rear image of a display panel PN, and FIG. 13 is a cross-sectional view of a display device for explaining that an image has a three-dimensional effect.

Referring to FIGS. 11 to 13, in the display device 100 according to the exemplary embodiment of the present disclosure, a mirror MR is disposed on the rear surface of the display panel PN to implement an image displayed on the front surface of the display panel PN to have a three-dimensional effect. Further, the display device 100 displaying a three-dimensional image may be used for devices in various fields.

For example, referring to FIG. 11, when the display device 100 (not shown in FIG. 11) is applied to a vehicle, the display device 100 may be applied to the instrument panel CL, the central information display CID, and the co-driver display CDD. In addition, the display device 100 may be applied to a component disposed outside of a vehicle capable of providing information to a driver, such as a side mirror.

Referring to FIG. 12, assuming that the display device 100 (not shown in FIG. 12) is applied to the instrument panel CL of the vehicle, a scale and a needle may be displayed on the front surface of the display panel PN by driving the plurality of first pixels PX1, and a scale emphasis design disposed along the outline of the scale and a battery may be displayed on the rear surface of the display panel PN by driving the plurality of second pixels PX2. In this case, the scale emphasis design and the battery image displayed on the rear surface of the display panel PN may have a depth, that is, a three-dimensional effect, during the process of being reflected by the mirror MR and emitted to the front surface of the display panel PN again. The scale emphasis design and the battery of the rear image may appear to be floating in the space behind the front image composed of a scale and a needle. Accordingly, the user USER (see for example FIG. 13) may recognize that the rear image is displayed after a predetermined distance from the front image, and the user USER located on the front side of the display panel PN may feel the three-dimensional effect while watching the rear image having a distance from the front image together with the front image.

Specifically, referring to FIG. 13, the user USER may view an image of the front surface of the display panel PN by first light L1 emitted to the front surface of the display panel PN from the plurality of first pixels PX1.

The second light L2 emitted from the plurality of second pixels PX2 to the rear surface of the display panel PN may be reflected by the mirror MR on the rear surface of the display panel PN and then directed to the front surface of the display panel PN again. The second light L2 reflected from the mirror MR may be emitted to the front surface of the display panel PN through the transmissive area TA of the display panel PN. Accordingly, the user USER may view the image on the rear surface of the display panel PN from the second light L2 reflected from the mirror MR and finally emitted to the front surface of the display panel PN.

In this case, when the distance between the display panel PN and the mirror MR is d, the user USER may recognize that the second light L2 is emitted from the virtual display panel PNa positioned at a position having a distance of 2d from the display panel PN. A plurality of second light L2 reflected from the mirror MR may form a virtual image on the rear surface of the mirror MR. A plurality of second light L2 reflected from the mirror MR may form a floating image of a virtual image on the plane of the virtual display panel PNa having an interval of 2d from the display panel PN.

For example, assuming that the second light L2 emitted from the first point P1 of the display panel PN is reflected by the mirror MR and emitted to the front surface of the display panel PN, a virtual light path L2i extending in a straight line from the second light L2 reflected by the mirror MR may be set. The virtual optical path L2i may intersect the first virtual line P1NL extending in the normal direction from the first point P1 at the first virtual point P1i, and a virtual image of the rear image may be formed at the first virtual point P1i. In this case, an interval between the first virtual point P1i and the first point P1 may be 2d. Accordingly, the user USER may recognize the virtual display panel PNa on which the first virtual point P1i is formed as if a rear image composed of the second light L2 is displayed. In other words, the user USER may recognize that the rear image composed of the plurality of second light L2 is output from the virtual display panel PNa. Accordingly, the user USER located on the front surface of the display panel PN may feel a three-dimensional effect by viewing a front image composed of a plurality of first lights L1 and a rear image composed of a plurality of second lights L2 and having a depth.

Accordingly, in the display device 100 according to the exemplary embodiment of the present disclosure, the mirror MR is disposed on the rear surface of the transparent double-sided light emitting display panel PN to display the front image of the display panel PN and the rear image having a depth together. The plurality of second light L2 emitted to the rear surface of the display panel PN may be reflected by the mirror MR on the rear surface of the display panel PN and directed to the front surface of the display panel PN. In this case, the plurality of second light L2 reflected from the mirror MR may form a virtual image at the position of the virtual display panel PNa on the rear surface of the mirror MR, and the user USER recognizes that the rear image composed of the plurality of second light L2 is output from the position of the virtual display panel PNa to feel the three-dimensional effect of the rear image. Accordingly, the display device 100 is configured by the transparent double-sided light emitting display panel PN and the mirror MR to display the front image and the rear image having a three-dimensional effect on the front surface of the display panel PN, thereby implementing the display device 100 capable of displaying the 3D image.

In addition, in the display device 100 according to the exemplary embodiment of the present disclosure, only one display panel PN and the mirror MR are used to implement a 3D image, so that the structure of the display device 100 may be simplified and lightweight. Conventionally, in order to implement a 3D image, a pair of display panels was used, or a separate optical system was used. However, when a pair of display panels is used, the cost increases, and when an optical system is used, a 3D image may be viewed only at a specific viewing angle or position. In contrast, in the display device 100 according to the exemplary embodiment of the present disclosure, the mirror MR is disposed behind one display panel PN to simply implement a 3D image, thereby reducing manufacturing costs and reducing the weight of the display device 100. In addition, since a separate optical system is not used, an area in which 3D images may be viewed, that is, a viewing angle is not limited, and a user USER viewing one display device 100 at various positions may view 3D images of the same quality.

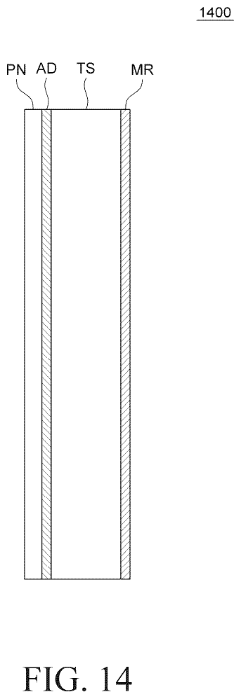

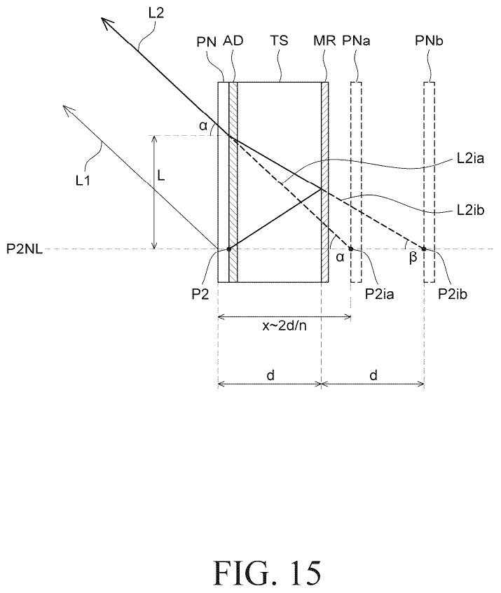

FIG. 14 is a schematic cross-sectional view of a display device according to another embodiment of the present disclosure. FIG. 15 is a schematic cross-sectional view for explaining a position of a virtual display panel of a display device according to another exemplary embodiment of the present disclosure. A display device 1400 of FIGS. 14 and 15 has the substantially same configuration as the display device 100 of FIGS. 1 to 13, except that an adhesive member AD and a transparent substrate TS are further disposed between the display panel PN and the mirror MR. Therefore, redundant description thereof will be omitted.

Referring to FIG. 14, a transparent substrate TS is disposed between the display panel PN and the mirror MR. The transparent substrate TS may be attached to the rear surface of the display panel PN through the adhesive member AD. The display panel PN is attached to the front surface of the transparent substrate TS and the mirror MR is attached to the rear surface of the transparent substrate TS. An interval between the display panel PN and the mirror MR may be adjusted by adjusting the thickness of the transparent substrate TS. The transparent substrate TS may be formed of glass or a transparent film, but is not limited thereto.

Referring to FIG. 15, the depth of the virtual image of the rear image composed of a plurality of second light L2 may vary depending on the refractive index of the transparent substrate TS. For example, the interval between the display panel PN and the mirror MR is d, the refractive index of the transparent substrate TS is n, in the process of being directed to the display panel PN by being reflected from the mirror MR, the refractive angle of the second light L2 refracted at the boundary between the transparent substrate TS and the display panel PN and emitted to the front surface of the display panel PN is a, the reflection angle of the second light L2 reflected from the mirror MR is J, and a distance between the second point P2 at which the second light L2 is initially emitted from the rear surface of the display panel PN and a point at which the second light L2 is reflected back to the rear surface of the display panel PN is assumed to be L. An interval x between the display panel PN and the 2-1-th virtual point P2ia at which the floating image of the virtual image is formed may be determined by the following equations 1 to 3.

$$L = 2 d tan β = x tan α \qquad [ Equation 1 ]$$

$$x = 2 d ( tan β / tan α ) \approx 2 d * β / α \qquad [ Equation 2 ]$$

$$n sin β = sin α \to 1 / n \approx β / α \qquad [ Equation 3 ]$$

The 2-2-th virtual light path L2ib extending from the second light L2 having the reflection angle β is the same light path as in the case where the second light L2 is not refracted as shown in FIG. 13. Therefore, when the second light L2 is emitted to the front surface of the display panel PN without being refracted, a virtual image may be formed at the 2-2-th virtual point P2ib at which the 2-2-th virtual light path L2ib and the second virtual line P2NL intersect. Accordingly, when the second light L2 having the reflection angle β is not refracted and travels straight to be emitted to the front surface of the display panel PN, the second virtual display panel PNb on which the virtual image is formed may have a distance of 2d from the display panel PN.

However, the refractive index of the transparent substrate TS may be different from the refractive index 1 of air, and the interval between the virtual display panel PNa (also referred to as “first virtual display panel PNa”) and the display panel PN in the display device 1400 according to another exemplary embodiment of the present disclosure may be about 2d/n.

Referring to Equation 1, the distance L between the second point P2 at which the second light L2 is initially emitted and the point at which the second light L2 is finally emitted to the front surface of the display panel PN may be derived from the reflection angle β and the refraction angle α.

Equation 2 is summarized based on Equation 1, and from Equations 1 and 2, it can be seen that the interval x between the display panel PN and the first virtual display panel PNa has a value of about 2d*(β/α).

Equation 3 is an equation based on Snell's law that the product of the sine value of the angle of refraction and the refractive index is equal to the sine value of the angle of incidence. Therefore, referring to Equation 3, it may be derived that 1/n has a value of about β/α by substituting the refraction angle β and the incident angle α by the transparent substrate TS into Equation 3.

Finally, by substituting 1/n, which is the value of β/α derived from Equation 3, into Equation 2, it can be derived that the interval x between the display panel PN and the first virtual display panel PNa has a value of about 2d/n.

Accordingly, the 2-1-th virtual light path L2ia extending from the refracted second light L2 may intersect with the second virtual line P2NL extending in the normal direction from the second point P2 at the 2-1-th virtual point P2ia, and a virtual image of the rear image may be formed at the 2-1-th virtual point P2ia. In this case, an interval x between the 2-1-th virtual point P2ia and the second point P2 may be about 2d/n as described above.

Therefore, the user USER (not shown in FIG. 15) may recognize that a rear image composed of the second light L2 is displayed on the plane on which the 2-1-th virtual point P2ia is formed, that is, the first virtual display panel PNa. In other words, the user USER may recognize that the rear image composed of the plurality of second light L2 is output from the first virtual display panel PNa.

In addition, an interval 2d/n between the position where the virtual image is formed and the display panel PN may also be applied to the display device 100 of FIGS. 1 to 13. For example, in the display device 100 of FIGS. 1 to 13, since air between the display panel PN and the mirror MR has a refractive index of 1, an interval between a position where a virtual image is formed and the display panel PN may be about 2d.

Accordingly, in the display device 1400 according to another exemplary embodiment of the present disclosure, the transparent substrate TS is disposed between the display panel PN and the mirror MR to stably couple and fix the display panel PN and the mirror MR to each other. The display panel PN and the mirror MR are attached to both surfaces of the transparent substrate TS so that the gap between the display panel PN and the mirror MR may be constantly configured with the thickness of the transparent substrate TS. Further, the transparent substrate TS may support the display panel PN and the mirror MR to maintain a stable coupling state. Further, the transparent substrate TS supports the display panel PN to be flat to prevent the display panel PN from sagging.

In the display device 1400 according to another exemplary embodiment of the present disclosure, the depth of the rear image may be adjusted based on the thickness and refractive index of the transparent substrate TS. An interval between the display panel PN and the mirror MR may be determined by the thickness of the transparent substrate TS. Therefore, the distance d between the display panel PN and the mirror MR may vary depending on the thickness of the transparent substrate TS. Further, various materials constituting the transparent substrate TS may be configured to adjust the refractive index of the transparent substrate TS. An interval x between the first virtual display panel PNa on which the virtual image is formed and the display panel PN may have a value of about 2d/n. In 2d/n, d is the same value as the thickness of the transparent substrate TS and n is the refractive index of the transparent substrate TS so that the position of the first virtual display panel PNa in which the virtual image is formed may be determined by the thickness and the refractive index of the transparent substrate TS. For example, as the thickness of the transparent substrate TS increases, the depth of the virtual image increases, and as the refractive index of the transparent substrate TS increases, the depth of the virtual image may decrease. Accordingly, the position of the first virtual display panel PNa and the depth of the rear image may be adjusted by adjusting the thickness and the refractive index of the transparent substrate TS.

Although the specific structure of the display panel PN has been described above in conjunction with the accompanying drawings, the specific structure of the display panel PN described above is exemplary and not limiting. In practice, the specific structure of the display panel PN can be designed as needed. For example, the light emitting element 120 may be a light emitting element other than a LED and a micro-LED, such as an organic light-emitting diode (OLED). In an example where the light emitting element 120 is an OLED, the light emitting element 120 may include a first electrode, a second electrode disposed on the first electrode, and an organic light-emitting layer disposed between the first electrode and the second electrode. One of the first electrode and the second electrode may be an anode, and the other of the first electrode and the second electrode may be a cathode. For example, the first electrode and/or the second electrode may be a transparent electrode or a non-transparent electrode. In some examples, the materials forming the first electrode and the second electrode may be different depending on the first pixel PX1 and the second pixel PX2. For example, in the first pixel PX1, the first electrode may be formed of a metal with high reflectivity, so that the first electrode may reflect a light emitted from the organic light-emitting layer to guide it to the front surface of the display panel PN, in which case, for example, the lower reflective layer BRL may be omitted. For example, in the second pixel PX2, the second electrode may be formed of a metal with high reflectivity, so that the second electrode may reflect the light emitted from the organic light-emitting layer to guide it to the back surface of the display panel PN, in which case, for example, the upper reflective layer TRL may be omitted.

The exemplary embodiments of the present disclosure can also be described as follows:

A display device according to an exemplary embodiment of the present disclosure includes a transparent display panel configured to emit light on both sides, and a mirror disposed on a rear surface of the display panel, wherein a first light displaying a front image on a front surface of the display panel is emitted to the front surface of the display panel, and a second light displaying a rear image on a rear surface of the display panel is reflected by the mirror to be emitted to the front surface of the display panel.

The display panel may include a display area in which a front image and a rear image are displayed, and the display area may include a plurality of pixel areas in which a plurality of first pixels emitting first light and a plurality of second pixels emitting second light are disposed, and a transmissive area disposed between the plurality of pixel areas and configured to transmit light.

The display panel may further include a substrate, a plurality of lower reflective layers disposed on a front surface of the substrate in the plurality of first pixels, a plurality of light emitting elements disposed on the lower reflective layer in the plurality of first pixels, and disposed on the front surface of the substrate in the plurality of second pixels, and a plurality of upper reflective layers disposed on the plurality of light emitting elements in the plurality of second pixels, the plurality of lower reflective layers may be configured to reflect the first light of the plurality of first pixels toward the front surface of the substrate, and the plurality of upper reflective layers may be configured to reflect the second light of the plurality of second pixels toward the rear surface of the substrate.

Each of the plurality of pixel areas may include an emission area overlapping the plurality of light emitting elements, and a non-transmissive area which is a remaining area excluding the emission area.

According to another feature of the present disclosure, the plurality of upper reflective layers may be configured to reflect the second light toward the mirror, and the second light reflected from the mirror may be configured to be emitted to the front surface of the display panel through the transmissive area of the display panel.

The second light emitted to the front surface of the display panel may be configured to generate a virtual image of the rear image on the rear surface of the mirror.

According to another feature of the present disclosure, the second light emitted to the front surface of the display panel may be configured to generate a floating image of a rear image on the rear surface of the mirror.

The display panel and the mirror are disposed to be spaced apart from each other with a first interval, and the interval between the display panel and the virtual image of the rear image may be twice the first interval.

According to another feature of the present disclosure, the depth of the virtual image of the rear image may be twice the first interval.

The display apparatus may further include a transparent substrate disposed between the display panel and the mirror, and an adhesive member disposed between the transparent substrate and the display panel.

According to another feature of the present disclosure, the refractive index of the transparent substrate is different from 1, and the second light, which is reflected from the mirror and directed from the transparent substrate to the front surface of the display panel, may be refracted at the boundary between the transparent substrate and the display panel.

According to another feature of the present disclosure, the interval between the display panel and the mirror may be a first interval, and the interval between the display panel and the virtual image of the rear image may be a value obtained by dividing a value of twice the first interval by the refractive index of the transparent substrate.

According to another feature of the present disclosure, the depth of the virtual image of the rear image may increase as the thickness of the transparent substrate increases, and may decrease as the refractive index of the transparent substrate increases.

A display device according to another exemplary embodiment of the present disclosure includes: a display panel including a transmissive area and a first pixel and a second pixel disposed outside the transmissive area, the first pixel being configured to emit front light toward a front surface of the display panel, and the second pixel being configured to emit rear light toward a rear surface of the display panel; and a mirror spaced apart from the display panel and configured to reflect the rear light such that the reflected rear light travels to the front surface of the display panel through the transmissive area.

According to another feature of the present disclosure, each of the first pixel and the second pixel may include a light-emitting element, and the display device may further include a lower reflective layer disposed below the light emitting element in the first pixel and an upper reflective layer disposed above the light emitting element in the second pixel.

According to another feature of the present disclosure, in a plan view, an area of the lower reflective layer may be larger than an area of the light emitting element in the first pixel and/or an area of the upper reflective layer may be larger than an area of the light emitting element in the second pixel.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A display device, comprising:
a transparent display panel configured to emit double-sided light; and
a mirror disposed on a rear surface of the display panel,
wherein a first light displaying a front image on a front surface of the display panel is emitted to the front surface of the display panel, and
a second light displaying a rear image on a rear surface of the display panel is reflected by the mirror to be emitted to the front surface of the display panel.

2. The display device according to claim 1, wherein the display panel includes a display area in which the front image and the rear image are displayed, and
the display area includes:
a plurality of pixel areas in which a plurality of first pixels emitting the first light and a plurality of second pixels emitting the second light are disposed; and
a transmissive area disposed between the plurality of pixel areas and configured to transmit light.

3. The display device according to claim 2, wherein the display panel further includes:
a substrate;
a plurality of lower reflective layers disposed on a front surface of the substrate in the plurality of first pixels;
a plurality of light emitting elements disposed on the lower reflective layer in the plurality of first pixels, and disposed on the front surface of the substrate in the plurality of second pixels; and
a plurality of upper reflective layers disposed on the plurality of light emitting elements in the plurality of second pixels,
wherein the plurality of lower reflective layers is configured to reflect the first light of the plurality of first pixels toward the front surface of the substrate, and the plurality of upper reflective layers are configured to reflect the second light of the plurality of second pixels toward the rear surface of the substrate.

4. The display device according to claim 3, wherein each of the plurality of pixel areas includes:
an emission area overlapping the plurality of light emitting elements; and
a non-transmissive area which is a remaining area excluding the emission area.

5. The display device according to claim 3, wherein the plurality of upper reflective layers is configured to reflect the second light toward the mirror and
the second light reflected from the mirror is emitted to the front surface of the display panel through the transmissive area of the display panel.

6. The display device according to claim 5, wherein the second light emitted to the front surface of the display panel is configured to generate a virtual image of the rear image on the rear surface of the mirror.

7. The display device according to claim 5, wherein the second light emitted to the front surface of the display panel is configured to generate a floating image of the rear image on the rear surface of the mirror.

8. The display device of claim 6, wherein the display panel and the mirror are disposed to be spaced apart from each other with a first interval, and
an interval between the display panel and the virtual image of the rear image is twice the first interval.

9. The display device according to claim 8, wherein a depth of the virtual image of the rear image is twice the first interval.

10. The display device of claim 6, further comprising:
a transparent substrate disposed between the display panel and the mirror; and
an adhesive member disposed between the transparent substrate and the display panel.

11. The display device according to claim 10, wherein
the second light, which is reflected from the mirror and directed from the transparent substrate to the front surface of the display panel, is refracted at a boundary between the transparent substrate and the display panel.

12. The display device according to claim 11, wherein an interval between the display panel and the mirror is a first interval, and
an interval between the display panel and the virtual image of the rear image is a value obtained by dividing a value of twice the first interval by a refractive index of the transparent substrate.

13. The display device according to claim 12, wherein a depth of the virtual image of the rear image increases as a thickness of the transparent substrate increases, and wherein the depth of the virtual image of the rear image decreases as the refractive index of the transparent substrate increases.

14. A display device, comprising:
a display panel including a transmissive area and a first pixel and a second pixel disposed outside the transmissive area, the first pixel being configured to emit front light toward a front surface of the display panel, and the second pixel being configured to emit rear light toward a rear surface of the display panel; and
a mirror spaced apart from the display panel and configured to reflect the rear light such that the reflected rear light travels to the front surface of the display panel through the transmissive area.

15. The display device of claim 14, wherein each of the first pixel and the second pixel includes a light-emitting element, and
the display device further includes a lower reflective layer disposed below the light-emitting element in the first pixel and an upper reflective layer disposed above the light-emitting element in the second pixel.

16. The display device of claim 15, wherein, in a plan view, an area of the lower reflective layer is larger than at least one of an area of the light emitting element in the first pixel or an area of the upper reflective layer is larger than an area of the light emitting element in the second pixel.
